(19) United States
(12) Patent Application Publication
(10) Pub. No.: US 2010/0151649 A1
(43) Pub. Date: Jun. 17, 2010

(54) Method of forming a minute pattern and method of manufacturing a transistor using the same

(76) Inventors: Sung-Dae Suk, Seoul (KR); Dong-Won Kim, Seongnam-si (KR); Yun-Young Yeoh, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/654,332

(22) Filed: Dec. 17, 2009

(30) Foreign Application Priority Data
Dec. 17, 2008 (KR) 10-2008-0128515

(51) Int. Cl. H01L 21/336; H01L 21/28

(52) U.S. Cl. 438/303; 438/585; 257/E21.19; 257/E21.409

(57) ABSTRACT

A method of forming a minute pattern includes forming mold patterns spaced apart from each other on an underlying structure, forming polysilicon spacers on sidewalls of the mold patterns, oxidizing the polysilicon spacers to form oxide layer patterns, and forming the minute pattern in a gap between the oxide layer patterns.

### BACKGROUND

1. Field

Example embodiments relate to a method of forming a minute pattern, and a method of manufacturing a transistor using the same. More particularly, example embodiments relate to a method of forming a minute pattern having a narrow width, and a method of manufacturing a transistor using the same.

2. Description of the Related Art

As high integration of semiconductor devices has increased, it may be required to form a minute pattern having a very narrow width. Particularly, because an area of an active region in a semiconductor substrate may be reduced, a gate electrode of a transistor may have a narrow width.

However, it may be difficult to form a gate electrode having a desired narrow width, e.g., a width smaller than a critical photolithography width, by the conventional photolithography process. Further, forming a gate electrode having a uniform width on an entire upper surface of a semiconductor substrate may be difficult. Thus, it may be difficult to form a pattern having a uniform and desired narrow width on the entire upper surface of the semiconductor substrate by the conventional photolithography process.

### SUMMARY

Embodiments are therefore directed to a method of forming a minute pattern and a method of manufacturing a transistor using the same, which substantially overcome one or more of the problems due to the limitations and disadvantages of the related art.

It is therefore a feature of an embodiment to provide a method of forming a minute pattern by depositing a conductive material in a gap between oxidized polysilicon spacers on sidewalls of adjacent mold patterns.

It is therefore another feature of an embodiment to provide a method of manufacturing a transistor having a gate electrode formed by depositing a conductive material in a gap between oxidized polysilicon spacers on sidewalls of adjacent mold patterns.

At least one of the above and other features and advantages may be realized by providing a method of forming a minute pattern. In the method of forming the minute pattern, mold patterns may be formed on an underlying structure. The mold patterns may be spaced apart from each other. Polysilicon spacers may be formed on sidewalls of the mold patterns. The polysilicon spacers may be oxidized to form oxide layer patterns. The minute pattern may be formed in a gap between the oxide layer patterns.

In some example embodiments, the method may further include removing the mold patterns from the minute pattern. Forming the mold patterns may include defining an initial gap between facing sidewalls of adjacent mold patterns, the polysilicon spacers being formed the on sidewalls of the initial gap. Forming the mold patterns may include forming the initial gap to have a critical width as determined by a photolithography process, the gap between the oxide layer patterns being formed to be narrower than the initial gap. Oxidizing the polysilicon spacers may include forming oxide layer patterns between adjacent mold patterns, the oxide layer patterns having a greater width than a width of the polysilicon spacers. Oxidizing the polysilicon spacers may include forming the gap between the oxide layer patterns to have a substantially uniform width along a first direction, the first direction being substantially perpendicular to a direction parallel to a line connecting two adjacent mold patterns. Forming the minute pattern may include filling the gap between the oxide layer patterns with a conductive material, a width of the gap being controlled by a degree of oxidation of the oxide layer patterns.

At least one of the above and other features and advantages may also be realized by providing a method of manufacturing a transistor. In the method of manufacturing the transistor, a buffer layer may be formed on a substrate having an active pattern. Mold patterns may be formed on the buffer layer. Polysilicon spacers may be formed on sidewalls of the mold patterns. The polysilicon spacers may be oxidized to form oxide layer patterns. The buffer layer exposed between the oxide layer patterns may be partially removed. A gate structure may be formed in a gap between the oxide layer patterns. Impurities may be implanted into the active region of the substrate at both sides of the gate structure to form impurity regions.

In some example embodiments, the active pattern may have a protrusion protruded from an upper surface of the substrate. In some example embodiments, forming the mold patterns may include using polysilicon, the mold patterns and the polysilicon spacers being formed integrally.

In some example embodiments, forming the buffer layer may include forming a silicon nitride layer on the substrate, and oxidizing an upper surface of the silicon nitride layer to form a silicon oxide layer on the silicon nitride layer. Further, removing the buffer layer may include removing the silicon oxide layer and the silicon nitride layer until the upper surface of the substrate may be exposed. Alternatively, removing the buffer layer may include removing only the silicon oxide layer.

In some example embodiments, forming the gate structure may include oxidizing the silicon nitride layer between the oxide layer patterns to form a gate insulating layer on the substrate, and forming a gate electrode in the gap between the oxide layer patterns.

In some example embodiments, forming the buffer layer may include forming a metal oxide layer on the substrate, and forming a silicon oxide layer on the metal oxide layer. Further, removing the buffer layer may include removing only the silicon oxide layer.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 to 5 illustrate cross-sectional views of a method of forming a minute pattern in accordance with some example embodiments;

FIGS. 6 to 17 illustrate perspective views and cross-sectional views of a method of manufacturing a transistor in accordance with some example embodiments;

FIGS. 18 to 20 illustrate perspective views and cross-sectional views of a method of manufacturing a transistor in accordance with some other example embodiments;

FIGS. 21 and 22 illustrate cross-sectional views of a method of manufacturing a transistor in accordance with some other example embodiments;

FIGS. 23 and 24 illustrate cross-sectional views of a method of manufacturing a transistor in accordance with some other example embodiments; and

FIGS. 25 and 26 illustrate cross-sectional views of a method of manufacturing a transistor in accordance with some other example embodiments.

### DETAILED DESCRIPTION

Korean Patent Application No. 10-2008-0128515, filed on Dec. 17, 2008, in the Korean Intellectual Property Office, and entitled: “Method of Forming a Minute Pattern and Method of Manufacturing a Transistor Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In the drawing figures, the dimensions of layers and regions may be exaggerated for clarity of illustration.

It will also be understood that when a layer or element is referred to as being “on,” “connected to,” or “coupled to” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. In contrast, when an element is referred to as being “directly on,” “directly connected to,” “directly coupled to,” or “directly between” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” elements or features would then be oriented as “upper” elements or features. Thus, the exemplary term “lower” may encompass both an orientation of lower and upper. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Method of Forming a Minute Pattern

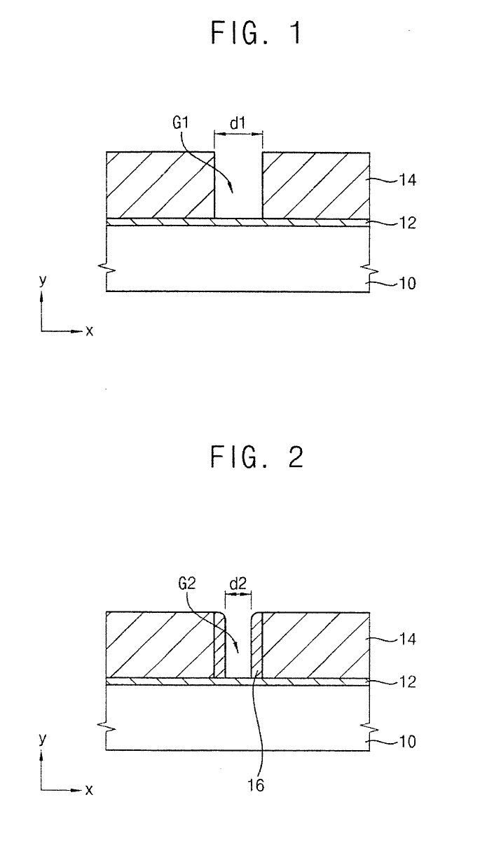

FIGS. 1 to 5 illustrate cross-sectional views of a method of forming a minute pattern in accordance with some example embodiments.

Referring to FIG. 1, an etch stop layer 12 may be formed on an underlying structure 10. In some example embodiments, the underlying structure 10 may be used for forming a minute pattern. The underlying structure 10 may include a semiconductor substrate. Alternatively, the underlying structure 10 may include a lower pattern or a lower layer on the semiconductor substrate.

In some example embodiments, the etch stop layer 12 may function to protect an upper surface of the underlying structure 10. Alternatively, forming the etch stop layer 12 may be omitted for simplifying the method of this example embodiment.

Further, the etch stop layer 12 may include a single material layer. For example, the etch stop layer 12 may include a silicon nitride layer, a silicon oxide layer, etc.

Alternatively, the etch stop layer 12 may include a multi-layered structure, e.g., a structure including at least two layers. For example, the etch stop layer 12 may include a silicon nitride layer and a silicon oxide layer on the silicon nitride layer.

A mold layer (not shown) may be formed on the etch stop layer 12. In some example embodiments, the mold layer may include a single material layer. For example, the mold layer may include a silicon nitride layer, a silicon oxide layer, etc. The mold layer may include a material different from that of the etch stop layer 12.

Alternatively, the mold layer may include a multi-layered structure. For example, the mold layer may include a polysilicon layer and a silicon nitride layer on the polysilicon layer.

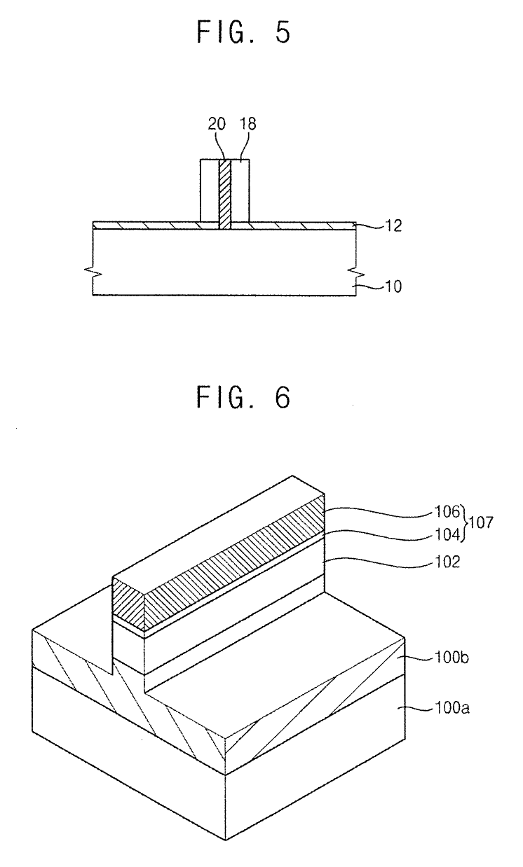

The mold layer may be patterned by a photolithography process to form mold patterns 14 on the etch stop layer 12. In some example embodiments, the mold layer patterns 14 may be spaced apart from each other to form a first gap G1 having a first width d1 along the x-axis, e.g., the first gap G1 may be formed between two adjacent mold patterns 14. The etch stop layer 12 may be exposed through the first gap G1. A minute pattern may be formed in the first gap G1, as will be discussed in more detail below with reference to FIGS. 4-5. The first gap G1 between the mold patterns 14 may be reduced to a critical gap formed by the photolithography process.

Referring to FIG. 2, a polysilicon layer (not shown) may be formed on upper surfaces, i.e., surfaces facing away from the underlying structure 10, of the mold patterns 14 and the etch stop layer 12. For example, the polysilicon layer may fill the first gap G1. In some example embodiments, the first gap G1 between the mold patterns 14 may not be fully filled with the polysilicon layer. The polysilicon layer may be anisotropically etched to form polysilicon spacers 16 on sidewalls of the mold patterns 14, i.e., along surfaces extending between upper and lower surfaces of the mold patterns 14. That is, the polysilicon spacers 16 may be on inner sidewalls of the first gap G1. For example, the polysilicon spacers 16 may extend along an entire depth of the first gap G1 along the y-axis to cover inner sidewalls thereof. The polysilicon spacers 16 may have a predetermined thickness along the x-axis, so the first gap G1 may be narrowed by the thickness of the polysilicon spacers 16 to form a second gap G2 between the mold patterns 14. The second gap G2 may have a second width d2 along the x-axis exposing the etch stop layer 12.

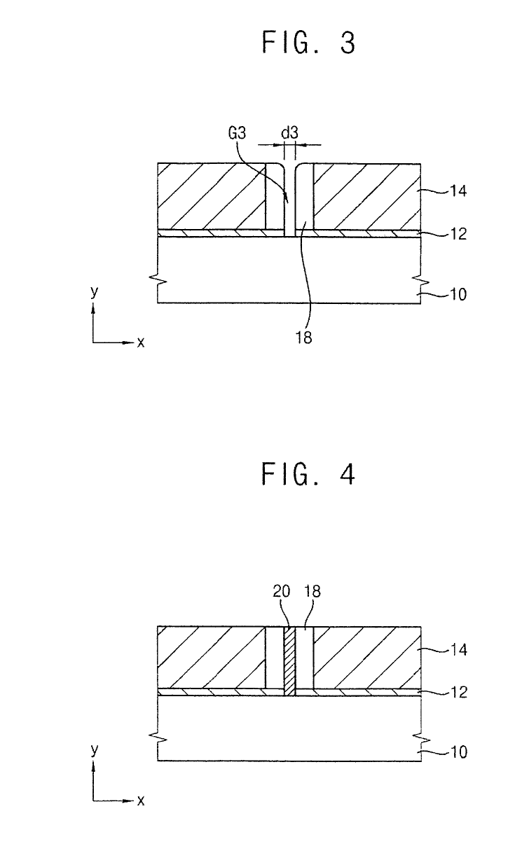

Referring to FIG. 3, the polysilicon spacers 16 may be oxidized to form oxide layer patterns 18 on the sidewalls of the mold patterns 14. In some example embodiments, the oxidation process may include a thermal oxidation process, a radical oxidation process, etc. Further, the oxidation process may include a dry oxidation process, a wet oxidation process, etc.

When the polysilicon spacers 16 are oxidized, volumes of the polysilicon spacers 16 may be expanded. That is, the oxide layer patterns 18 may have a width greater than that of the polysilicon spacers 16 along the x-axis, thereby define a third gap G3 having a third width d3 along the x-axis. Since the oxide layer patterns 18 have a greater width than that of the polysilicon spacers 16 along the x-axis, the third width d3 of the third gap G3 between the oxide layer patterns 18 may be narrower than the second width d2 of the second gap G2 between corresponding polysilicon spacers 16.

In some example embodiments, the polysilicon spacers 16 may be entirely oxidized, e.g., entire surfaces of the polysilicon spacers 16, to form the oxide layer patterns 18. Alternatively, the spacers 16 may be partially oxidized. A degree of oxidation, e.g., partial or entire, may affect the volume increase of the polysilicon spacers 16, thereby facilitating control of the third width d3 of the third gap G3. The third width d3 of the third gap G3 between the oxide layer patterns 18 may correspond to a width of the minute pattern to be formed subsequently in the third gap G3.

As further illustrated in FIG. 3, a portion of the etch stop layer 12 exposed through the third gap G3 may be removed. The upper surface of the underlying structure 10 may be exposed through the third gap G3.

Referring to FIG. 4, the third gap G3 between the oxide layer patterns 18 may be filled, e.g., completely filled, with a layer (not shown). In some example embodiments, the layer may include a conductive layer. For example, the conductive layer may include a metal layer, a metal nitride layer, etc. Here, the metal layer and the metal nitride layer may not be etched readily using an etching gas. Thus, the third gap G3 may be filled with the metal layer and/or the metal nitride layer after forming the mold patterns 14, so that the minute pattern may be readily formed.

The layer may be planarized until upper surfaces of the oxide layer patterns 18 are exposed to form a minute pattern 20 in the third gap G3. In some example embodiments, the minute pattern 20 may have a width substantially the same as the third width d3 of the third gap G3 between the oxide layer patterns 18.

Referring to FIG. 5, the mold patterns 14 may then be removed. In some example embodiments, the mold patterns 14 may be removed, e.g., by a wet etching process. Thus, the oxide layer patterns 18 may remain on both sidewalls of the minute pattern 20. The oxide layer patterns 18 may function as sidewall spacers of the minute pattern 20. Alternatively, the oxide layer patterns 18, as well as the mold patterns 14, may be removed. Additionally, although not depicted in the drawing figures, portions of the etch stop layer 12 under the mold patterns 14 may be removed.

According to example embodiments, the minute pattern 20 may have a smaller width than a critical width formed by a photolithography process. Particularly, the third gap G3 may be formed by expanding the volumes of the polysilicon spacers 16 on the sidewalls of the second gap G2, i.e., facing sidewalls of adjacent mold patterns 14, so the third gap G3 may be formed to be narrower than the second gap G2 without using, e.g. conventional photolithography. Since the minute pattern 20 may be formed in the third gap G3, the width of the minute pattern 20, i.e., the width of the third gap G3, may be smaller than a critical width of the conventional photolithography process, i.e., a minimum width achieved by a photolithography process. For example, the width of the minute pattern 20 may be about 10 nm or smaller.

In contrast, formation of a conventional minute pattern may require wet-etching sidewalls of patterns to reduce widths thereof after an anisotropic etching process or a damascene process. However, control of the wet etching process may be difficult, thereby widths of the patterns on an entire upper surface of a semiconductor substrate may not be uniform.

According to example embodiments, however, the wet etching process with respect to the sidewalls of the minute patterns may not be required after forming the minute patterns. Therefore, the widths of the minute patterns on the entire upper surface of the semiconductor substrate may be uniform.

Method of Manufacturing a Transistor

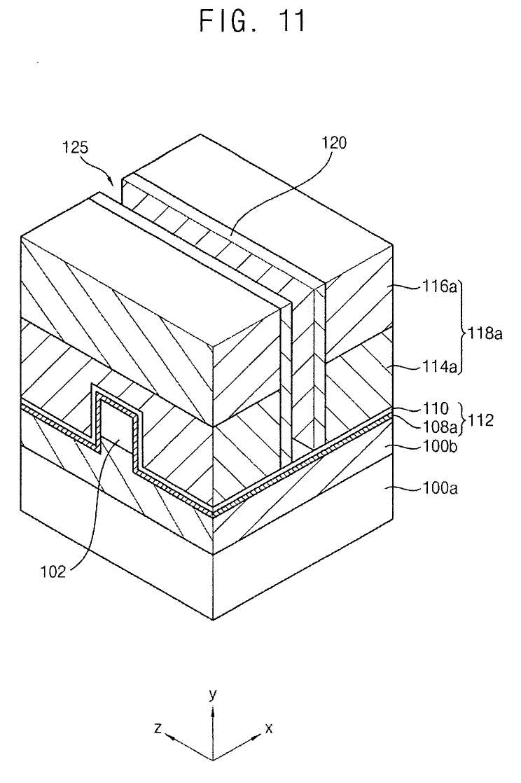

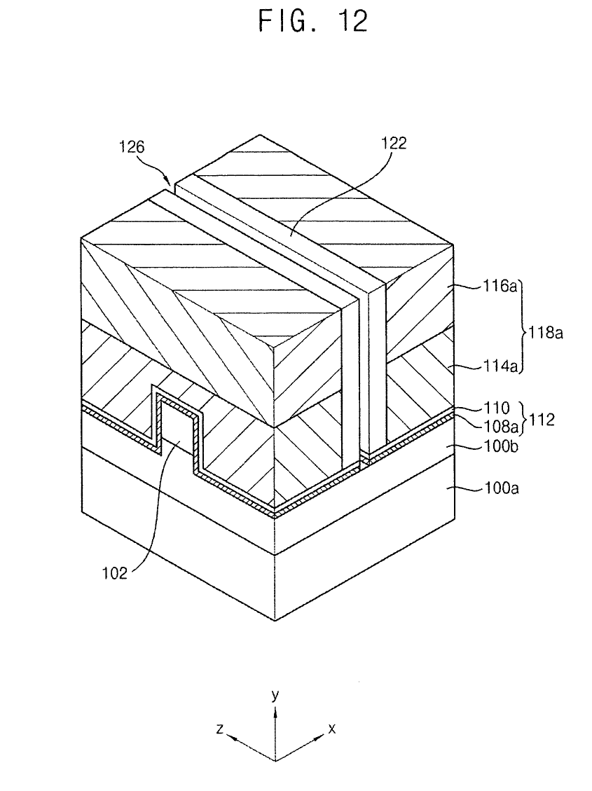

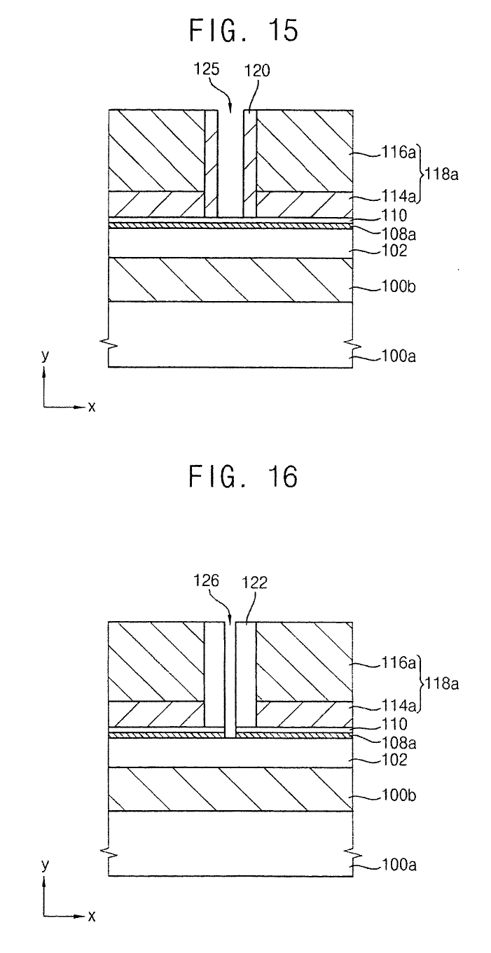

FIGS. 6 to 17 illustrate perspective views and cross-sectional views of a method of manufacturing a transistor in accordance with some example embodiments. FIGS. 6 to 14 illustrate perspective views of stages in the manufacturing method, and FIGS. 15 to 17 illustrate cross-sectional views of the active region in FIGS. 11, 12, and 14, respectively. It is noted that a gate electrode in the transistor of this example embodiment may be manufactured by the method described previously with reference to FIGS. 1 to 5.

Referring to FIG. 6, a silicon-on-insulator (SOI) substrate may be prepared. In some example embodiments, the SOI substrate may include a bulk silicon layer 100a, a buried insulating layer 100b, and a silicon layer.

A first hard mask pattern 107 for defining an active region may be formed on the SOI substrate. In some example embodiments, a pad oxide layer (not shown) and a first silicon nitride layer (not shown) may be sequentially formed on the SOI substrate. The pad oxide layer may prevent the first silicon nitride layer from making contact with an upper surface of the silicon layer in the SOI substrate. The first silicon nitride layer may be patterned, e.g., by a photolithography process, to form a first silicon nitride layer pattern 106. The first silicon nitride layer pattern 106 may have a linear shape extending in a first direction. The pad oxide layer may be etched to form a pad oxide layer pattern 104, thereby forming the first hard mask pattern 107 including the sequentially stacked pad oxide layer pattern 104 and first silicon nitride layer pattern 106.

The silicon layer in the SOI substrate may be, e.g., anisotropically, etched using the first hard mask pattern 107 as an etch mask to form an active pattern 102. In some example embodiments, after etching the silicon layer, the buried insulating layer 100b may be additionally etched. Since the buried insulating layer 100b is under the silicon layer, i.e., the buried insulating layer 100b is between the bulk silicon layer 100a and the silicon layer, the silicon layer may be anisotropically etched to form the isolated active pattern 102, thereby completing an isolation process.

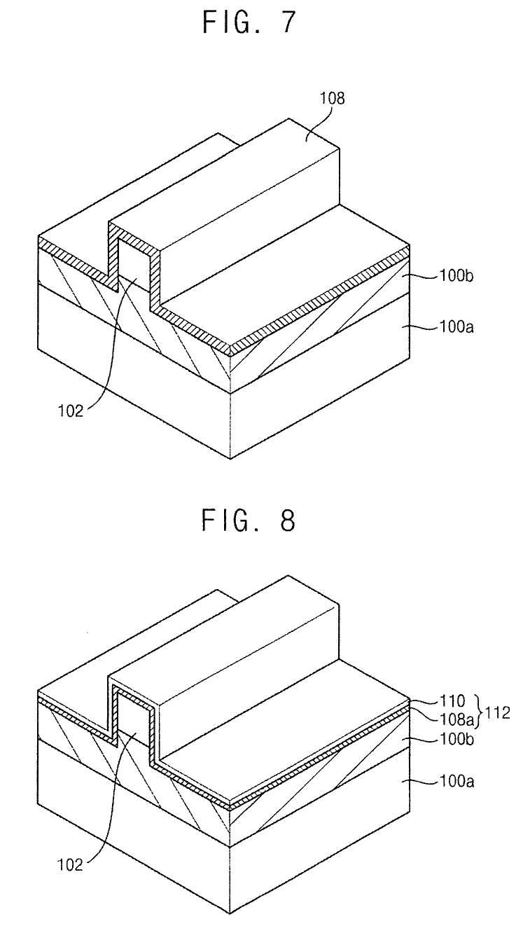

Referring to FIG. 7, the first hard mask pattern 107 including the pad oxide layer pattern 104 and the first silicon nitride layer pattern 106 may then be removed to expose an upper surface, i.e., a surface facing away from the bulk silicon layer 100a, of the active pattern 102. In some example embodiments, in order to prevent damages of the active pattern 102 during removal of the first hard mask pattern 107, the first hard mask pattern 107 may be removed, e.g., by a wet etching process. The active pattern 102 may protrude above an upper surface of the buried insulating layer 100b.

A second silicon nitride layer 108 may be formed, e.g., conformally, on the active pattern 102 and on the upper surface of the buried insulating layer 100b. In some example embodiments, the second silicon nitride layer 108 may protect the active pattern 102 during subsequent processes.

Referring to FIG. 8, the second silicon nitride layer 108 may be partially oxidized to form a first silicon oxide layer 110 on the second silicon nitride layer 108. Further, a third silicon nitride layer 108a may be formed by partially oxidizing the second silicon nitride layer 108. For example, as illustrated in FIG. 8, the third silicon nitride layer 108a and the first silicon oxide layer 110 may be sequentially arranged on the buried insulating layer 100b to define a buffer layer 112. The third silicon nitride layer 108a may have a smaller thickness than that of the second silicon nitride layer 108. It is noted that the silicon nitride in the second silicon nitride layer 108 may not be oxidized by a thermal oxidation process. Thus, the second silicon nitride layer 108 may be oxidized, e.g., by a radical oxidation process.

Therefore, the buffer layer 112 including the sequentially stacked third silicon nitride layer 108a and first silicon oxide layer 110 may be formed by the oxidation process. Alternatively, a silicon nitride layer and a silicon oxide layer may be sequentially formed by a chemical vapor deposition (CVD) process to form the buffer layer 112.

In some example embodiments, the third silicon nitride layer 108a corresponding to a lower layer of the buffer layer 112 may have an etching selectivity higher than that of the buried insulating layer 100b. The first silicon oxide layer 110 corresponding to an upper layer of the buffer layer 112 may have an etching selectivity higher than that of polysilicon. Alternatively, the upper layer and the lower layer of the buffer layer 112 may include other materials, which may be different from silicon nitride and silicon oxide, having etching selectivities higher than those of the buried insulating layer 100b and polysilicon, respectively. Further, the buffer layer 112 may include a single layer, e.g., a single a silicon nitride layer. In this case, the oxidation process of the second silicon nitride layer 108 may be omitted.

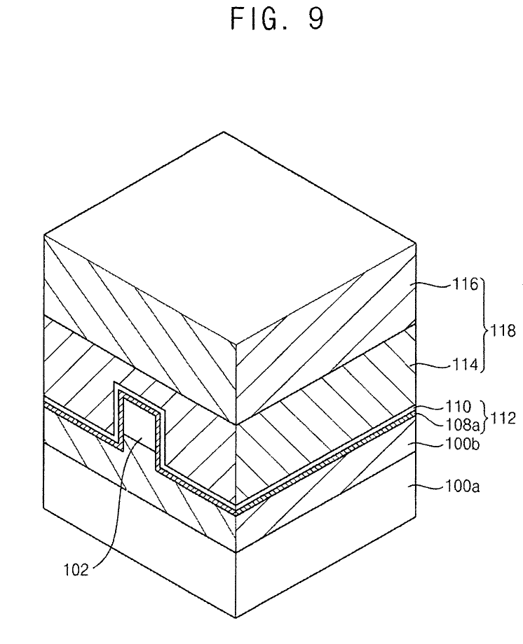

Referring to FIG. 9, a first polysilicon layer 114 may be formed, e.g., conformally, on the first silicon oxide layer 110. For example, a lowermost surface of the first polysilicon layer 114 facing the buried insulating layer 100b may be positioned lower than an uppermost surface of the active pattern 102. The first polysilicon layer 114 may be planarized by a chemical mechanical polishing (CMP) process. In some example embodiments, the planarized first polysilicon layer 114 may have an upper surface higher than that of the active pattern 102. Thus, the first polysilicon layer 114 may be configured to cover the active pattern 102.

A fourth silicon nitride layer 116 may be formed on the first polysilicon layer 114 to form a mold layer 118 including the sequentially stacked first polysilicon layer 114 and fourth silicon nitride layer 116. In some example embodiments, the fourth silicon nitride layer 116 may be used as a hard mask for patterning the first polysilicon layer 114.

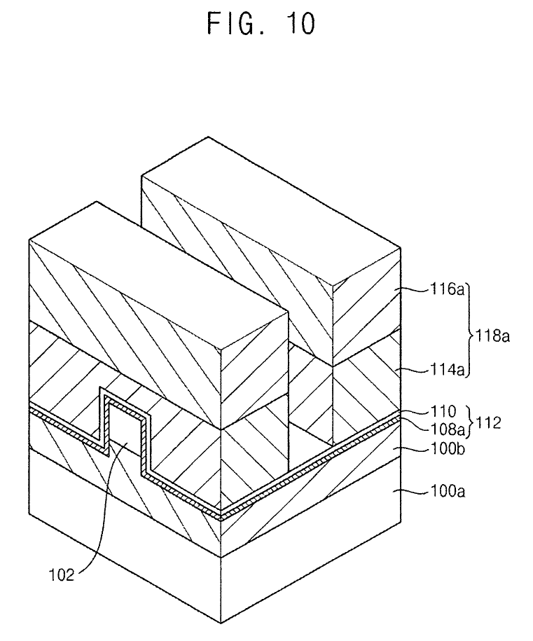

Referring to FIG. 10, the fourth silicon nitride layer 116 may be patterned, e.g., by a photolithography process, to form a second silicon nitride layer pattern 116a. The first polysilicon layer 114 may be, e.g., anisotropically, etched using the second silicon nitride layer pattern 116a as an etch mask and the first silicon oxide layer 110 as an etch stop layer to form a first polysilicon pattern 114a, thereby completing mold patterns 118a including the sequentially stacked first polysilicon pattern 114a and second silicon nitride layer pattern 116a. In some example embodiments, each of the mold patterns 118a may include the sequentially stacked first polysilicon pattern 114a and second silicon nitride layer pattern 116a. Alternatively, the mold patterns 118a may include only a silicon nitride layer. In this case, forming the first polysilicon layer 114 may be omitted. Adjacent mold patterns 118a may include a gap therebetween, so the gap may have a width in the first direction and a length in a second direction, i.e., a direction substantially perpendicular to the first direction. Therefore, the gap may be substantially perpendicular to the active region 102. The width of the gap may be substantially uniform along an entire length of the gap and depth of the gap, i.e., along a third direction.

In some example embodiments, the mold patterns 118a may be used as dummy patterns for forming a gate electrode. The gate electrode may be formed between the mold patterns 118a according to the method for forming the minute pattern 20 described previously with reference to FIGS. 1-5. Hereinafter, a method of manufacturing the gate electrode will be described in more detail with reference to FIGS. 11-17.

FIG. 15 illustrates a cross-sectional view along a lengthwise direction of the active pattern in FIG. 11. Referring to FIGS. 11 and 15, a second polysilicon layer (not shown) may be formed on upper surfaces and sidewalls of the mold patterns 118a. In some example embodiments, gaps between the mold patterns 118a may not be fully filled with the second polysilicon layer.

The second polysilicon layer may be anisotropically etched to form polysilicon spacers 120 on the sidewalls of the mold patterns 118a. The gap between the mold patterns 118a may be narrowed by a width of the polysilicon spacers 120 to form a gap 125. Further, the second polysilicon layer may be anisotropically etched to expose the first silicon oxide layer 110 on the active pattern 102. However, because the first silicon oxide layer 110 is not etched in the anisotropic etching process, the active pattern 102 may not be damaged during the anisotropic etching process.

FIG. 16 illustrates a cross-sectional view taken along the lengthwise direction of the active pattern in FIG. 12. Referring to FIGS. 12 and 16, the polysilicon spacers 120 may be oxidized to form silicon oxide layer pattern 122. In some example embodiments, the oxidation process may include, e.g., a thermal oxidation process, a radical oxidation process, etc. In order to allow stable volume expansion of the polysilicon spacers 120, the polysilicon spacers 120 may be oxidized by the radical oxidation process. Further, the oxidation process may include a dry oxidation process, a wet oxidation process, etc.

As described above with reference to FIGS. 1-5, the volume expansion generated during oxidation of the polysilicon spacers 120, i.e., formation of the silicon oxide layer patterns 122, may define a gap 126 between the silicon oxide layer patterns 122, e.g., between facing sidewalls of adjacent silicon oxide layer patterns 122. That is, the width of the gap 125 may be reduced to form the gap 126. The gap 126 may be narrower than the gap 125 between the polysilicon spacers 120, i.e., along the x-axis, due to the volume expansion of the polysilicon spacers 120. As a result, the gate electrode, which is to be formed in the gap 126 between the silicon oxide layer patterns 122, may have a very narrow width. Here, the oxidation process may have high stability and reproduction. Therefore, the width and volume expansion of the silicon oxide layer patterns 122 may be substantially uniform. Further, the width of the gap 126 between the silicon oxide layer patterns 122 may also be substantially uniform, i.e., along the x and z axis.

In some example embodiments, polysilicon in the polysilicon spacers 120 may be entirely converted into silicon oxide in the silicon oxide layer patterns 122. Alternatively, the polysilicon in the polysilicon spacers 120 may be partially converted into the silicon oxide in the silicon oxide layer patterns 122. Thus, the gap 126 between the silicon oxide layer patterns 122, i.e., a width of the gap 126 between the adjacent silicon oxide layer patterns 122, may be adjusted by controlling the oxidation process, e.g., amount and/or thickness of the polysilicon spacers 120 oxidized.

A portion of the first silicon oxide layer 110 exposed between the silicon oxide layer patterns 122 may be removed by a dry etching process. The third silicon nitride layer 108a may be removed by a dry etching process or a wet etching process to expose the upper surface of the active pattern 102.

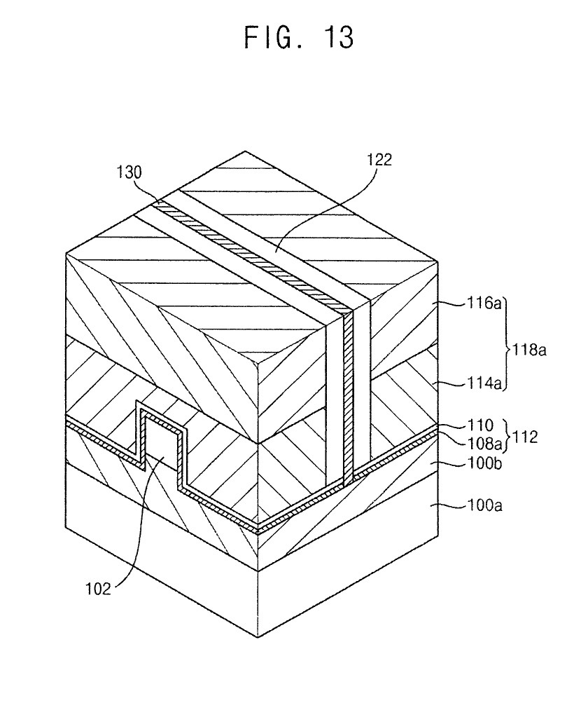

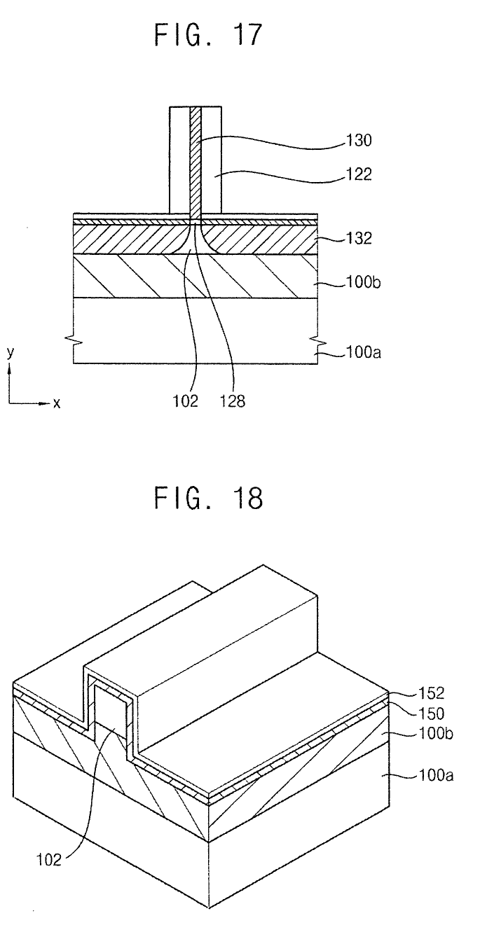

Referring to FIG. 13, the exposed upper surface of the active pattern 102 may be oxidized to form a gate oxide layer 128 (See FIG. 17). A conductive layer (not shown) may be formed on the gate oxide layer 128 to fill, e.g., completely fill, the gap 126 between the silicon oxide layer patterns 122. In some example embodiments, the conductive layer may include metal, metal nitride, metal silicide, etc. These may be used alone or in a combination thereof. For example, the conductive layer may include a titanium nitride layer.

The conductive layer may be planarized until the second nitride layer pattern 116a is exposed to form a gate electrode 130 in the gap 126. The gate electrode 130 may have a smaller width than a critical width formed by a photolithography process. Further, because the gate electrode 130 includes a metal with a low resistance, the gate electrode 130 may have a low resistance in spite of the narrow width of the gate electrode 130.

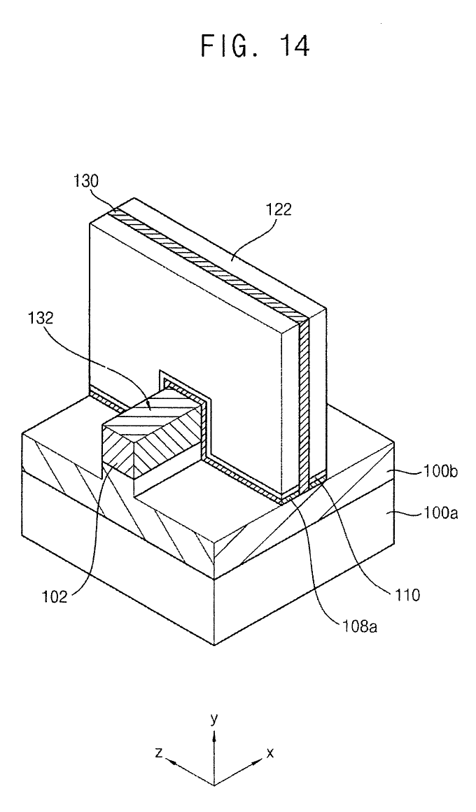

FIG. 17 illustrates a cross-sectional view taken along the lengthwise direction of the active pattern in FIG. 14. Referring to FIGS. 14 and 17, the second silicon nitride layer pattern 116a and the first polysilicon pattern 114a may be removed, e.g., by a wet etching process. The silicon oxide layer patterns 122 may remain along sidewalls of the gate electrode 130. The remaining silicon oxide layer patterns 122 may be used as offset spacers of the gate electrode 130.

Further, after performing the removal process, the active pattern 102 at both sides of the gate electrode 130 may be exposed. Impurities may be implanted into the exposed active pattern 102 to form source/drain regions 132.

Although not depicted in the drawing figures, a metal silicide pattern may be additionally formed on the source/drain regions 132. In some example embodiments, the metal silicide pattern may include, e.g., one or more of cobalt silicide, nickel silicide, etc. The metal silicide pattern may reduce resistances of the source/drain regions 132.

According example embodiments, a transistor may include a gate electrode with a very narrow width. Thus, the transistor may have a short channel length between the source/drain regions, so that scattering of charges in the channel region may be reduced. As a result, ballistic efficiency, e.g., movement and path, of the charges may be improved, so that the transistor may have an increased on-current and a rapid operational speed. Particularly, when the transistor includes a three-dimensional transistor having the upper surface and the sidewall of the active pattern used as the channel, a short channel effect may not be generated.

FIGS. 18 to 20 illustrate perspective views and cross-sectional views of a method of manufacturing a transistor in accordance with some other example embodiments.

Referring to FIG. 18, the SOI substrate including the bulk silicon layer 100a, the buried insulating layer 100b, and the silicon layer may be prepared. A first hard mask pattern (not shown) for defining an active region may be formed on the SOI substrate. The silicon layer may be etched using the first hard mask pattern as an etch mask to form the active pattern 102. The first hard mask pattern may then be removed.

A metal oxide layer 150 having a high dielectric constant may be formed on the active pattern 102. The metal oxide layer 150 may be used as a gate insulating layer. In some example embodiments, the metal oxide layer 150 may be formed by a CVD process, an atomic layer deposition (ALD) process, etc. The metal oxide layer 150 may include aluminum oxide, zirconium oxide, hafnium oxide, tantalum oxide, etc. These can be used alone or in a combination thereof.

A silicon oxide layer 152 may be formed on the metal oxide layer 150. In some example embodiments, the silicon oxide layer 152 may be formed by a CVD process, an ALD process, etc.

In this example embodiment, after forming the active pattern 102, the metal oxide layer 150 used as the gate insulating layer may be previously formed. The silicon oxide layer 152 for protecting the metal oxide layer 150 may be formed on the metal oxide layer 150.

Processes substantially the same as those described previously with reference to FIGS. 9 to 11 may be performed to form the mold pattern 118a and polysilicon spacers 120.

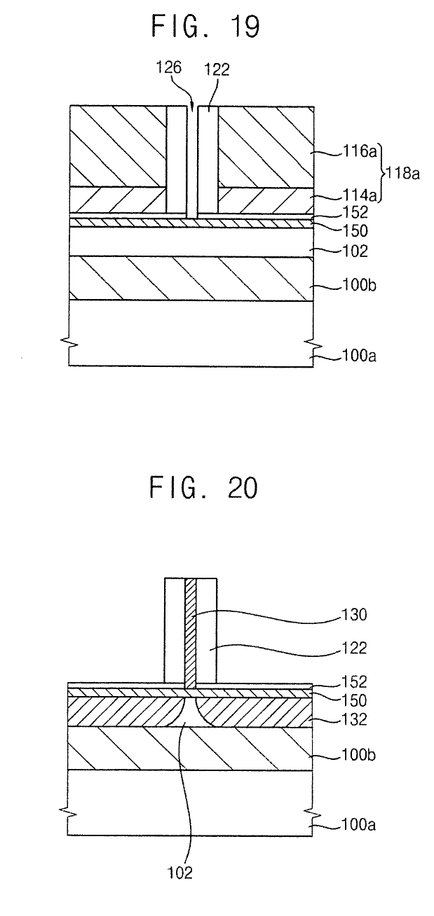

Referring to FIG. 19, the polysilicon spacers 120 may be oxidized to form the silicon oxide layer patterns 122. Here, the process for oxidizing the polysilicon spacers 120 may be substantially the same as described previously with reference to FIG. 12.

The silicon oxide layer 152 between the silicon oxide layer patterns 122 may be removed by a dry etching process. Here, the metal oxide layer 150 may remain. The remaining metal oxide layer 150 may be used as the gate insulating layer of the transistor.

Referring to FIG. 20, a conductive layer (not shown) may be formed on the metal oxide layer 150 to fill up the gap 126 between the silicon oxide layer patterns 122. The conductive layer may be planarized until an upper surface of the mold pattern 118a is exposed to form the gate electrode 130.

A process substantially the same as that described previously with reference to FIG. 14 may be performed to remove the mold pattern 118a. Impurities may be implanted into the active pattern 102 at both sides of the gate electrode 130 to form the source/drain regions 132. A metal silicide layer (not shown) may be additionally formed on the source/drain regions 132.

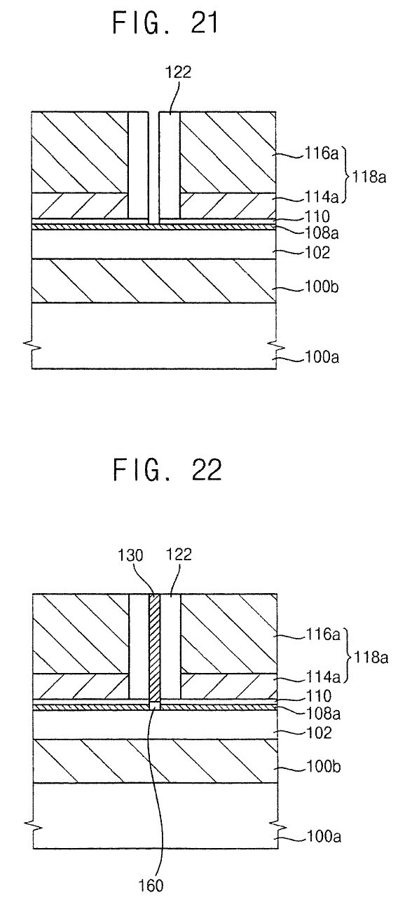

FIGS. 21 and 22 illustrate cross-sectional views of a method of manufacturing a transistor in accordance with some other example embodiments. It is noted that the method in FIGS. 21-22 is substantially the same as the method described previously with reference to FIGS. 6 to 17, with the exception of a process for forming a gate insulating layer.

First, processes substantially the same as those described previously with reference to FIGS. 6 to 11 may be performed to form the structure in FIG. 11. Next, referring to FIG. 21, the polysilicon spacers 120 may be oxidized to form the silicon oxide layer patterns 122. Here, the oxidation process may be substantially the same as described previously with reference to FIG. 12.

The silicon oxide layer 110 exposed between the silicon oxide layer patterns 122 may be removed by a dry etching process. In contrast, the third silicon nitride layer 108a may remain to be exposed between the silicon oxide layer patterns 122.

Referring to FIG. 22, the third silicon nitride layer 108a exposed between the silicon oxide layer patterns 122 may be oxidized to form a gate insulating layer 160 including silicon oxide. In some example embodiments, the oxidation process may include a radical oxidation process.

A conductive layer (not shown) may be formed on the gate insulating layer 160 to fill up the gap between the silicon oxide layer patterns 122. The conductive layer may be planarized until an upper surface of the mold pattern 118a is exposed to form the gate electrode 130.

A process substantially the same as that described previously with reference to FIG. 14 may be performed to remove the mold pattern 118a. Impurities may be implanted into the active pattern 102 at both sides of the gate electrode 130 to form the source/drain regions 132. A metal silicide layer (not shown) may be additionally formed on the source/drain regions 132.

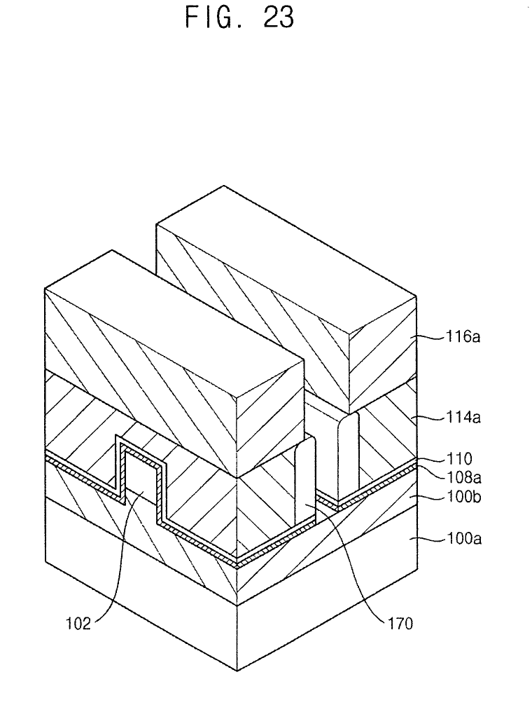

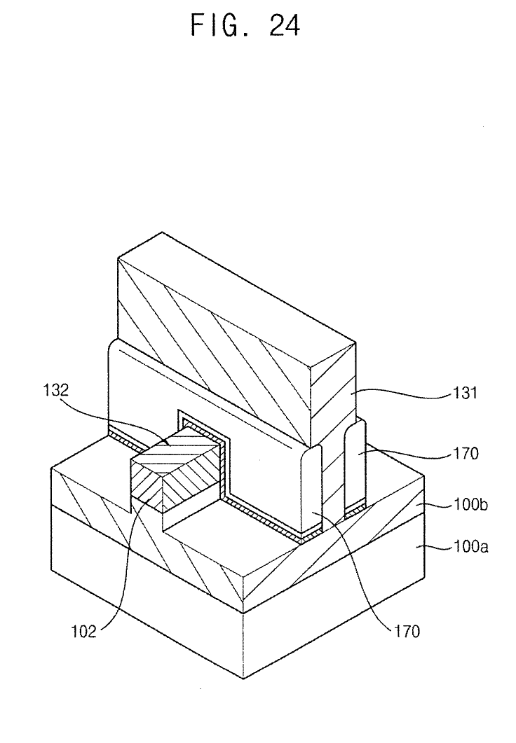

FIGS. 23 and 24 illustrate perspective views of a method of manufacturing a transistor in accordance with some other example embodiments. It is noted that the method in FIGS. 23-24 is substantially the same as the method described previously with reference to FIGS. 6 to 17, with the exception of a process for forming polysilicon spacers.

First, processes substantially the same as those described previously with reference to FIGS. 6 to 10 may be performed to form the structure in FIG. 10. Next, referring to FIG. 23, exposed sidewalls of the polysilicon patterns 114a in the mold pattern 118a may be oxidized to form silicon oxide layer patterns 170. In some example embodiments, the oxidation process may be substantially the same as that described previously with reference to FIG. 12. A volume expansion generated during oxidation of the polysilicon patterns 114a may be converted into the silicon oxide layer patterns 170. Thus, a gap between the silicon oxide layer patterns 170 may be narrower than a gap between the polysilicon patterns 114a. Although not depicted in drawing figures, a sidewall of the second silicon nitride layer pattern 116a on the polysilicon patterns 114a may be additionally oxidized together with the polysilicon patterns 114a.

The first silicon oxide layer 110 exposed between the silicon oxide layer patterns 170 may be removed by a dry etching process. The third silicon nitride layer 108a may be removed by a dry etching process or a wet etching process to expose the upper surface of the active pattern 102.

Processes substantially the same as those described with reference to FIGS. 13 and 14, although not depicted in drawings, may be performed to form a gate insulating layer, a gate electrode 131, and the source/drain regions 132 in FIG. 24. In some example embodiments, the gate electrode 131 may have an upper width and a lower width narrower than the upper width. That is, a lower portion of the gate electrode 131 corresponding to a channel may have a relatively narrow width. In contrast, an upper portion of the gate electrode 131 located higher, e.g., further from the buried silicon 100b, than the upper surface of the active pattern 102 may have a relatively wide width. According to this example embodiment, a process for forming polysilicon spacers separately from the mold patterns may be omitted, e.g., the mold patterns and spacers may be formed integrally as one element, so that the method may be more simplified.

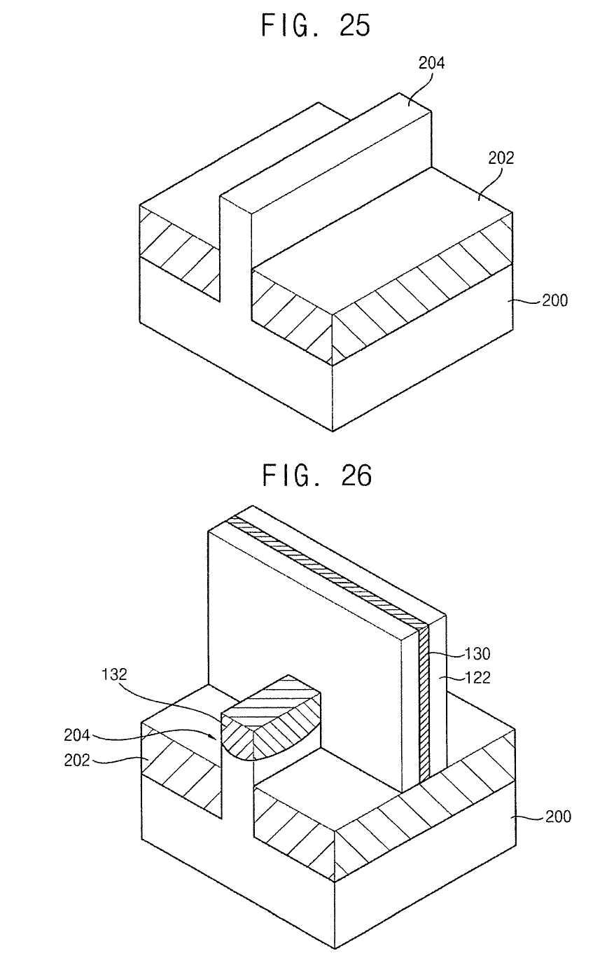

FIGS. 25 and 26 illustrate perspective views of a method of manufacturing a transistor in accordance with some other example embodiments. It is noted that the method in FIGS. 25-26 is substantially the same as the method described previously with reference to FIGS. 6 to 17, with the exception of a process for forming an active pattern.

Referring to FIG. 25, a bulk silicon substrate including single crystalline silicon may be prepared. A first hard mask pattern (not shown) for defining an active region may be formed on the substrate. In some example embodiments, the first hard mask pattern may include a pad oxide layer pattern and a first silicon nitride layer pattern sequentially stacked.

The substrate may be anisotropically etched using the first hard mask pattern to form isolation trenches. An insulating layer (not shown) may be formed on the substrate to fill up the trenches. The insulating layer may be planarized until an upper surface of the first hard mask pattern may be exposed to form preliminary isolation layer patterns (not shown).

The preliminary isolation layer patterns may be partially removed until side surfaces of the trenches are partially exposed to form isolation layer patterns 202 configured to partially fill the trenches. In some example embodiments, the preliminary isolation layer patterns may be removed by a wet etching process, a dry etching process, etc. In order to reduce damages of the side surfaces of the trenches, the preliminary isolation layer patterns may be preferably removed by the wet etching process. Further, an active pattern 204 may be formed between the isolation layer patterns 202 by the removal process. In some example embodiments, the active pattern 204 may be configured to protrude from upper surfaces of the isolation layer patterns 202.

Processes substantially the same as those described previously with reference to FIGS. 7 to 14 may be performed to form a gate insulating layer, the gate electrode 130, silicon oxide layer patterns 122, and source/drain regions 132 on the active pattern 204 in FIG. 26.

According to example embodiments, a minute pattern having a very narrow width may be readily formed. Thus, the methods may be used for processes for forming patterns having a very narrow width, e.g., a gate electrode, a wiring, etc. According to some example embodiments, the minute pattern formed by some example embodiments may have a width smaller than a critical width formed by a conventional method. Further, the minute pattern may have a uniform width. As a result, highly integrated semiconductor devices without the characteristic distribution may be manufactured by the methods of some example embodiments. Therefore, yield and productivity of the semiconductor device may be improved.

For example, the method may be used to form a transistor with a gate electrode having a very narrow width, i.e., a narrow channel, so that charge mobility may be improved and an on-current may be increased. Therefore, the transistor may have a rapid operational speed. Further, because the channel length of the transistor is uniform, characteristic distribution between a plurality of transistors may not be generated.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a minute pattern, the method comprising:
forming mold patterns spaced apart from each other on an underlying structure;
forming polysilicon spacers on sidewalls of the mold patterns;
oxidizing the polysilicon spacers to form oxide layer patterns; and
forming the minute pattern in a gap between the oxide layer patterns.

2. The method as claimed in claim 1, further comprising removing the mold patterns from the minute pattern.

3. The method as claimed in claim 1, wherein forming the mold patterns includes defining an initial gap between facing sidewalls of adjacent mold patterns, the polysilicon spacers being formed the on sidewalls of the initial gap.

4. The method as claimed in claim 3, wherein forming the mold patterns includes forming the initial gap to have a critical width as determined by a photolithography process, the gap between the oxide layer patterns being formed to be narrower than the initial gap.

5. The method as claimed in claim 1, wherein oxidizing the polysilicon spacers includes forming oxide layer patterns between adjacent mold patterns, the oxide layer patterns having a greater width than a width of the polysilicon spacers.

6. The method as claimed in claim 1, wherein oxidizing the polysilicon spacers includes forming the gap between the oxide layer patterns to have a substantially uniform width along a first direction, the first direction being substantially perpendicular to a direction parallel to a line connecting two adjacent mold patterns.

7. The method as claimed in claim 1, wherein forming the minute pattern includes filling the gap between the oxide layer patterns with a conductive material, a width of the gap being controlled by a degree of oxidation of the oxide layer patterns.

8. A method of manufacturing a transistor, the method comprising:
forming a buffer layer on an upper surface of a substrate having an active pattern;
forming mold patterns spaced apart from each other on the buffer layer;
forming polysilicon spacers on sidewalls of the mold patterns;
oxidizing the polysilicon spacers to form oxide layer patterns;
removing the buffer layer between the oxide layer patterns;
forming a gate structure in a gap between the oxide layer patterns; and
implanting impurities into the active region of the substrate at both sides of the gate structure to form impurity regions.

9. The method as claimed in claim 8, wherein the active pattern protrudes from the upper surface of the substrate.

10. The method as claimed in claim 8, wherein forming the buffer layer includes:
forming a silicon nitride layer on the substrate; and
oxidizing the silicon nitride layer to form a silicon oxide layer on the silicon nitride layer.

11. The method as claimed in claim 10, wherein removing the buffer layer includes entirely removing the silicon oxide layer and the silicon nitride layer to expose the upper surface of the substrate.

12. The method as claimed in claim 10, wherein removing the buffer layer includes removing only the silicon oxide layer.

13. The method as claimed in claim 12, wherein forming the gate structure includes:
oxidizing the silicon nitride layer between the oxide layer patterns to form a gate insulating layer on the substrate; and
forming a gate electrode in the gap between the oxide layer patterns.

14. The method as claimed in claim 8, wherein forming the buffer layer includes:
forming a metal oxide layer on the substrate; and
forming the silicon oxide layer on the metal oxide layer.

15. The method as claimed in claim 14, wherein removing the buffer layer includes removing only the silicon oxide layer.

16. The method as claimed in claim 8, wherein forming the mold patterns includes using polysilicon, the mold patterns and the polysilicon spacers being formed integrally.
